(19) United States
(12) Patent Application Publication
(10) Pub. No.: US 2025/0081383 A1
(43) Pub. Date: Mar. 6, 2025

(54) SERVER BASKET FOR USE IN AN IMMERSION COOLING TANK

(71) Applicant: LIQUIDSTACK HOLDING B.V., Amsterdam (NL)

(72) Inventors: Kar-Wing Lau, Hong Kong (HK); Wai Sing Cheng, Hong Kong (HK); Joseph Capes, Northborough, MA (US)

(21) Appl. No.: 18/950,868

(22) Filed: Nov. 18, 2024

Related U.S. Application Data
(63) Continuation of application No. PCT/IB2023/055091, filed on May 17, 2023.
(60) Provisional application No. 63/342,885, filed on May 17, 2022.
(60) Provisional application No. 63/342,888, filed on May 17, 2022.

(51) Int. Cl. H05K 7/14; H05K 7/20

(52) U.S. Cl. CPC H05K 7/1489; H05K 7/1491; H05K 7/20236; H05K 7/20772

(57) ABSTRACT

Server baskets for use in immersion tanks are described herein. In one example, a server basket may be configured to receive a computer server. The server basket may include a cable management housing that has one or more data and power ports. The cable management housing may be located at or proximate to a top portion of the server basket. When the server basket is immersed in dielectric fluid in an immersion tank, the cable management housing may be located above a liquid level, thereby providing convenient access to the one or more ports. A signal repeater may be located in the cable management housing and above the liquid level. The server basket may include support arms that can be deployed when removing the server from the dielectric fluid. The support arms may enable drip drying and fluid recapture by the immersion tank. Other examples may be claimed or described.

### CROSS-REFERENCE TO RELATED APPLICATIONS

Pursuant to 35 U.S.C. 120 and 365 (c), this application is a continuation of International Application PCT/IB2023/055091, filed on May 17, 2023, which designates the United States and claims priority to U.S. Application Nos. 63/342,885 and 63/342,888, each filed on May 17, 2022,and each hereby incorporated by reference in its entirety.

### TECHNICAL FIELD

The present disclosure relates to immersion cooling systems and, more specifically, to server baskets for housing electronic components in an immersion cooling tank.

### BACKGROUND

Data centers house information technology (IT) equipment for the purposes of storing, processing, and disseminating data and applications. IT equipment may include electronic devices, such as servers, storage systems, power distribution units, routers, switches, and firewalls.

IT equipment consumes electricity and produces waste heat as a byproduct. A data center may have hundreds or thousands of servers and require a dedicated IT cooling system to manage the waste heat. If the waste heat is not removed from the data center, ambient temperature within the data center may rise above an acceptable threshold and temperature-induced performance throttling of electronic devices (e.g., microprocessors) may occur, which is undesirable.

Direct liquid cooling systems can be used to capture waste heat from IT equipment. One form of direct liquid cooling is immersion cooling. In an immersion cooling system, an electronic device is immersed in dielectric fluid. Waste heat from the electronic device is transferred to the dielectric fluid and then rejected outside the data center through a suitable heat rejection system.

### SUMMARY

This summary is provided to introduce a selection of concepts in a simplified form that are further described below in the description. This summary is not intended to identify key features or essential features of the claimed subject matter, nor is it intended to be used to determine the scope of the claimed subject matter.

Server baskets for use in immersion tanks are described herein. In one aspect, a server basket may include a frame having a bottom portion, a top portion, a front portion, a rear portion, a first side portion, and a second side portion opposite the first side portion. The server basket may include a server cavity in the frame and configured to receive a computer server. The server basket may include a cable management housing extending from the top portion. The cable management housing may include one or more power and data connections. The server basket may include a cable pathway extending from the server cavity to the cable management housing. The server basket may include a signal repeater in the cable management housing. The server basket may include a handle assembly having a first end attached to the cable management housing and a second end attached to the frame. The server basket may include a first support arm attached to the first side portion and a second support arm attached to the second side portion. Together, the first support arm and the second support arm may support the server basket in an upright orientation when resting on a support surface, such as a top surface of an immersion tank. The first support arm may include a pin attached to the frame and a support arm having a slot through which the pin extends. The support arm may transition from a stowed configuration to a deployed configuration. The first support arm may include a spring-loaded arm that transitions from a stowed configuration to a deployed configuration. The server basket may include a first clip receiver attached to the first side portion and a second clip receiver attached to the second side portion. The first clip receiver may include a first plurality of openings and be configured to receive a first removable support arm. The second clip receiver may include a second plurality of openings and be configured to receive a second removable support arm. Together, the first support arm and the second support arm may be configured to support the server basket in an upright orientation when resting on a support surface, such as a top surface of an immersion tank.

In another aspect, a server basket may include a frame having a server cavity configured to receive a piece of IT equipment, such as a computer server. The server basket may include a cable management housing at or proximate to a top portion of the frame. The cable management housing may include a plurality of power and data connections. The server basket may include a signal repeater within the cable management housing. The server basket may include a guide system having a first guide rail on a first side of the frame and a second guide rail on a second side of the frame. The server basket may include a cable pathway extending from the server cavity to the cable management housing. The cable pathway may pass through a cable routing compartment. The server basket may include a hinge attaching the cable management housing to the frame, a top cover attached to the cable management housing, and a lifting eye attached to the top cover. Rotating the cable management housing about the hinge may reveal a server opening in the frame that provides access to the server cavity. The server basket may include a first support arm attached to a first side portion of the frame and a second support arm attached to a second side portion of the frame. The first support arm may include a pin attached to the frame and a support arm having a slot through which the pin extends, and the support arm may transition from a stowed configuration to a deployed configuration. The server basket may include a first support arm having a spring-loaded arm that transitions from a stowed configuration to a deployed configuration. The first support arm may be removable and have a pad that is configured to rest against a top surface of an immersion tank when the server basket is in a drying position.

In another aspect, a server basket may include a frame having a bottom portion, a top portion, a front portion, a rear portion, a first side portion, and a second side portion. The server basket may include a server cavity in the frame and configured to receive a computer server. The server basket may include a cable management housing extending upward from the frame. The cable management housing may include one or more power and data ports. The server basket may include a handle assembly extending from the cable management housing to the frame and a server retention device slidably attached to the handle assembly and configured to retain the computer server in the server cavity. The server basket may include a first support arm attached to the first side portion and a second support arm attached to the second side portion. The first support arm may include a pin attached to the frame and a support arm having a slot through which the pin extends, and the support may transition from a stowed configuration to a deployed configuration. The first support arm may include a spring-loaded arm that is configured to transition from a stowed configuration to a deployed configuration. The first support arm may be removable and include a fixed clip, a movable clip, and an adjustment screw to secure the movable clip in a position relative to the fixed clip.

### BRIEF DESCRIPTION OF DRAWINGS

The drawings are not necessarily to scale, and emphasis may instead be placed upon illustrating principles of the invention. Like numerals may identify like elements throughout the views and embodiments. In the detailed description, various embodiments are described with reference to the following drawings, in which:

FIG. 1A shows a front perspective view of a server basket for use in an immersion tank.

FIGS. 1B-D show steps for installing a server in the server basket of FIG. 1A. FIG. 1B shows a server being inserted into a server cavity of the server basket. FIG. 1C shows a handle assembly being installed after the server is inserted. FIG. 1D shows a server retention device being installed to secure the server within the server cavity.

FIG. 2 shows the server basket assembly of FIG. 1A being inserted into an immersion tank of an immersion cooling system.

FIGS. 3A-C show simplified views of the immersion cooling system of FIG. 2. FIG. 3A shows the immersion cooling system with a lid covering the opening. FIG. 3B shows several server baskets arranged vertically withing the immersion tank. FIG. 3C shows a server basket supported in an upright drying position within the opening of the immersion tank by a pair of spring-loaded support arms.

FIG. 4A shows the server basket of FIG. 1A with a server retention device and alternate handle.

FIGS. 4B-4D shows steps for installing the server retention device of FIG. 4A. FIG. 4B shows the server retention device loosely attached to the handle assembly. FIG. 4C shows the server retention device being positioned to contact the server. FIG. 4D shows the server retention device being secured to the upright member.

FIG. 5 shows a removable support arm for the server basket of FIG. 1A.

FIG. 6 shows the server basket of FIG. 1A with removable support arms installed.

FIG. 7 shows an exploded view of the server basket of FIG. 1A with removable support arms.

FIG. 8A shows the support arm of FIG. 5 with a movable clip in an unsecured position.

FIG. 8B shows the support arm of FIG. 5 with the movable clip in a secured position.

FIG. 9 shows the server basket of FIG. 1A with hinged support arms.

FIGS. 10A-C show cross-sectional side views of steps of deploying the hinged support arm of FIG. 9. FIG. 10A shows the hinged support in a stowed position. FIG. 10B shows the hinged support rotated upward. FIG. 10C shows the hinged support inserted into a retention pocket to hold the hinged support arm in a deployed position.

FIGS. 11A-C show steps for stowing the hinged support arm of FIG. 9. FIG. 11A shows the support arm being withdrawn from the retention pocket. FIG. 11B shows the support arm being rotated downward about the pin. FIG. 11C shows the support arm in a stowed position.

FIGS. 12A-F show an alternative embodiment of a server basket with a hinged cable management housing. FIGS. 12A and 12B shows front and rear perspective views of the server basket, respectively. FIG. 12C shows a rear perspective view of the server basket with a top cover partially opened. FIG. 12D shows an enlarged view of a hinge and cable routing compartment of FIG. 12C. FIG. 12E shows a rear perspective view of the server basket with top cover fully opened. FIG. 12 F shows a cross-sectional rear view of the server basket, exposing a cable pathway extending from a server cavity, through the cable routing compartment, and to the cable management housing.

### DETAILED DESCRIPTION OF EMBODIMENTS

In an immersion cooling system, there is a need to accurately position servers within the immersion tank. There is a need to make servers easily retrievable from the immersion tank, either by hand or with a crane or hoist. There is a need to support servers in a drying position prior to servicing or removal. Server baskets are described herein that address these needs. For example, server baskets are described herein that include guide systems to ensure accurate placement within the immersion tank. Server baskets are described herein that include handle assemblies to facilitate removal by hand or with a crane or hoist. Server baskets are described herein that include support arms to enable drip drying prior to servicing or removal.

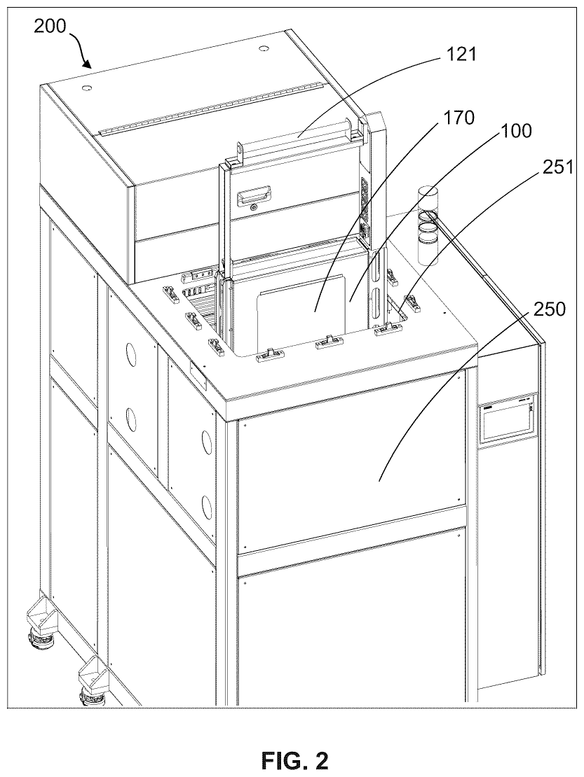

FIG. 2 shows an immersion cooling system 200. The immersion cooling system 200 may include an immersion tank 250. The immersion tank 250 may be partially filled with a dielectric fluid. The immersion tank 250 may include a tank opening 251. The tank opening 251 may be located at or near a top portion of the immersion tank 250 and provide access to an interior volume of the immersion tank. The immersion cooling system 200 may be configured to receive and cool one or more electronic devices, such as one or more computer servers 170 (“servers”) or network communication devices in the immersion tank 250.

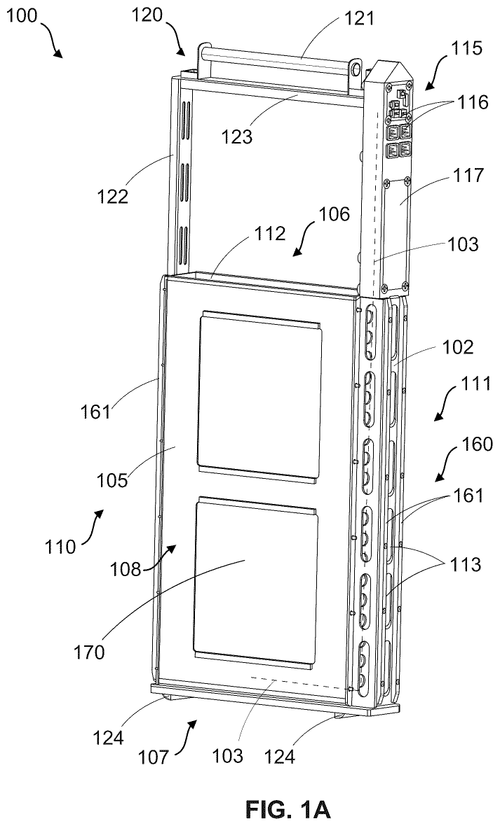

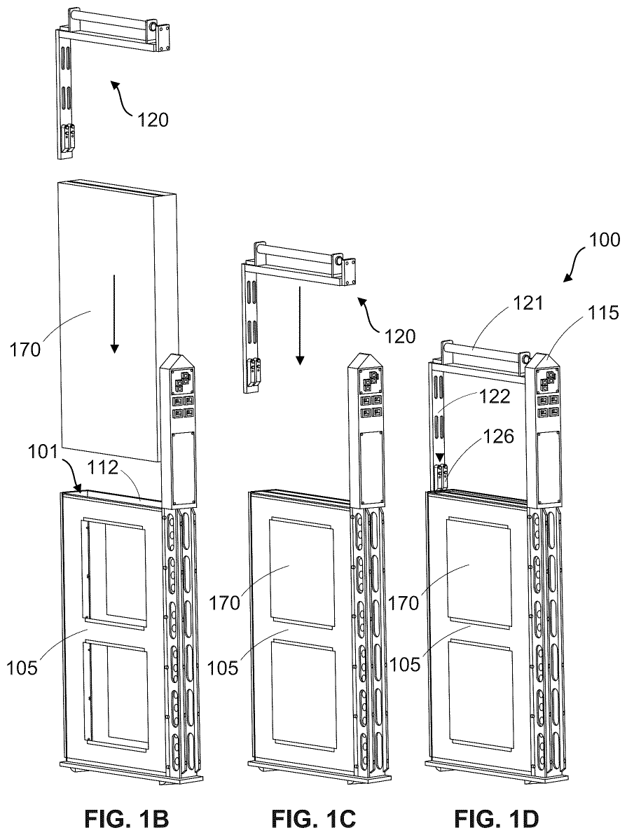

Prior to insertion of a server into the immersion tank 250, the server 170 may be installed in a server basket 100, as shown in FIGS. 1A-1D. FIGS. 1B-D show steps for installing a server 170 in the server basket 100. FIG. 1B shows a server 170 being inserted into a server cavity 101 of the server basket 100. FIG. 1C shows a handle assembly 120 being installed after the server 170 is inserted. A first end of the handle assembly 120 may be attached to the cable management housing 115, and a second end of the handle assembly 120 may be attached to the frame 105. FIG. 1D shows a server retention device 126 being installed to secure the server within the server cavity 101. The server basket 100 may then be inserted into the immersion tank 250 through the tank opening 251, as shown in FIG. 2. Upon insertion, the server 170 may be immersed in the dielectric fluid, thereby cooling the server 170 during operation.

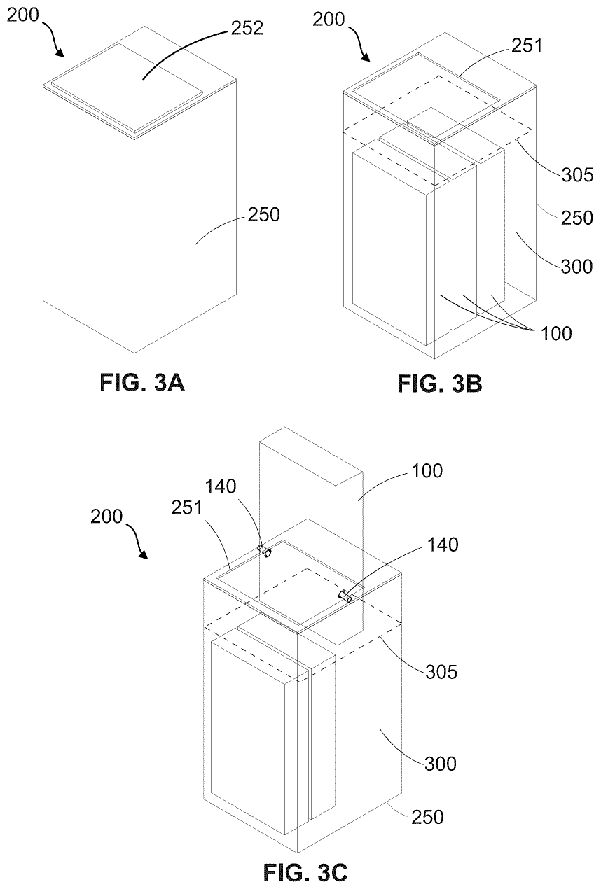

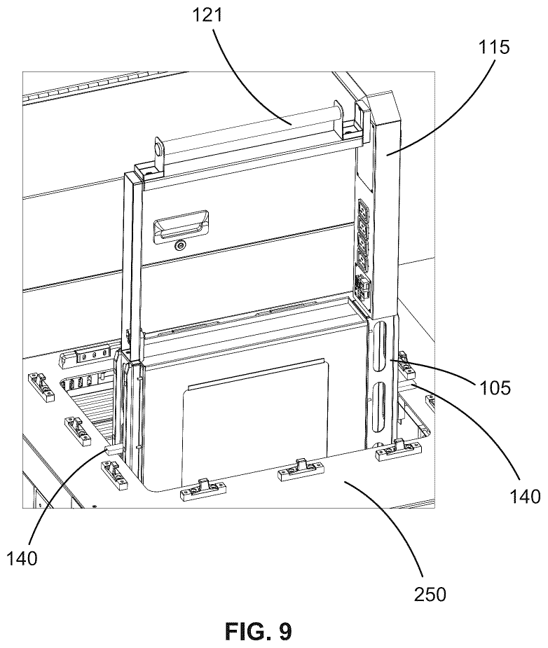

To facilitate servicing or replacing the server 170, the server basket 100 may be withdrawn from the immersion tank 250 from time to time. As the server basket 100 is withdrawn from the dielectric fluid 300, various cavities and surfaces of the server 170 and server basket 100 may retain dielectric fluid. To prevent fluid loss or spillage during removal, the server basket 100 may be raised above the liquid level 305, as shown in FIGS. 3C and 9, and allowed to drip dry for a period of time. Dripping fluid may return via gravity to the immersion tank 250 through the tank opening 251.

FIG. 3A-C show simplified views of the server basket 100 and immersion cooling system 200 of FIGS. 1 and 2, respectively. FIG. 3A shows the immersion cooling system 200 with a lid 252 covering the tank opening 251. FIG. 3B shows the lid 252 removed and multiple server baskets 100 visible within the immersion tank 250. To efficiently utilize space in the immersion tank 250, multiple server baskets 100 may be arranged adjacently in close proximity and substantially upright orientations. Due to the close proximity of the servers, there is a need to accurately and securely position the servers to avoid physical interference during insertion and removal. A guide system 160 is described herein that addresses this need for accurate positioning.

As shown in FIG. 3B, the liquid level 305 of the dielectric fluid 300 may be above the servers 170, resulting in the servers being fully immersed in fluid. FIG. 3C shows one of the server baskets 100 partially removed from the immersion tank 250 and having support arms 140 resting on a top surface of the immersion tank 250 proximate to the tank opening 251. The raised server basket 100 is supported above the liquid level 305 to allow the server 170 and server basket 100 to drip dry while capturing the dripping fluid in the immersion tank 250. Capturing the fluid is desirable since it mitigates the need to replenish lost fluid and avoids spillage on the floor beside the immersion tank, which could present a slip and fall hazard.

FIG. 1A shows a front perspective view of the server basket 100. The server basket 100 may include a frame 105. The frame 105 may include a top portion 106, a bottom portion 107, a front portion 108, a rear portion 109, a left side portion 110, and a right side portion 111 opposite the left side portion.

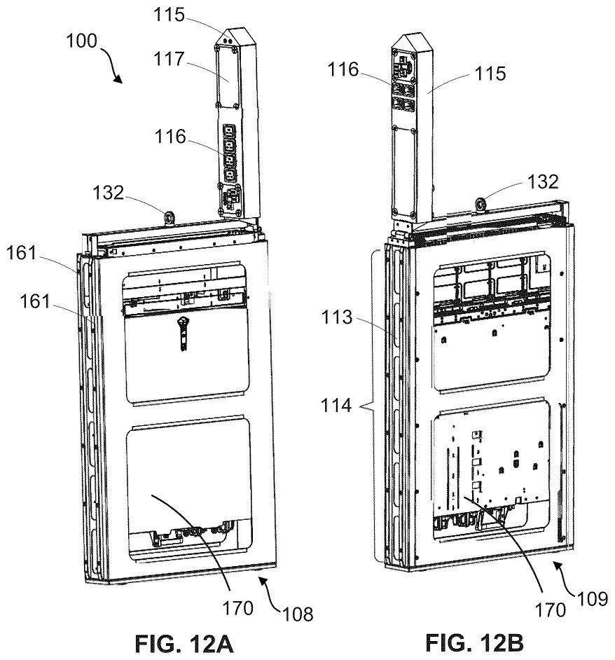

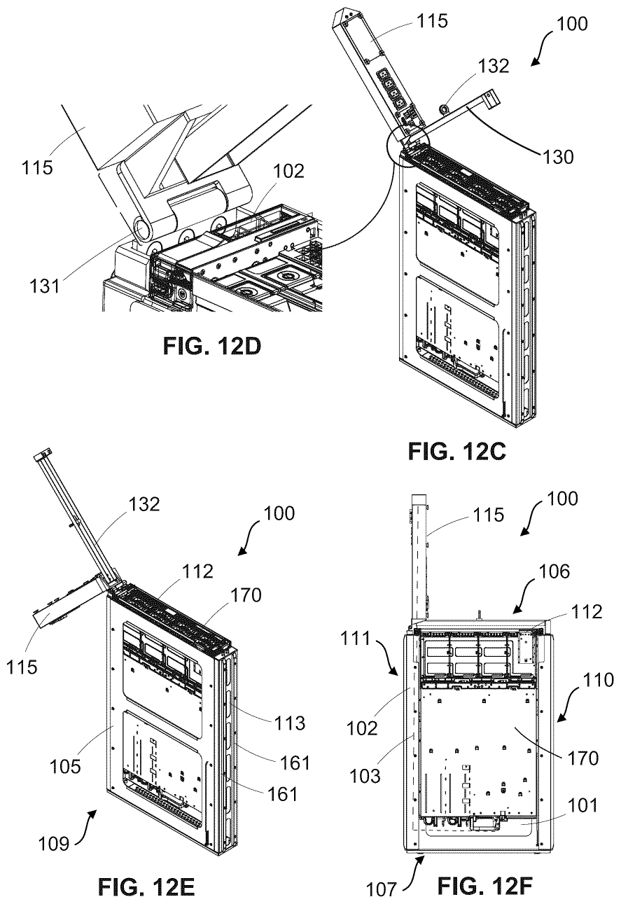

The server basket 100 may include a server cavity 101 configured to receive a server 170. FIG. 12F shows a cross-sectional rear view of the server basket 100 revealing a server cavity 101 within the frame 105. The server cavity 101 may be defined by one or more of the top portion 106, the bottom portion 107, the front portion 108, the rear portion 109, the left side portion 110, and the right side portion 111. The server 170 may be inserted into the server cavity 101 through a server opening 112 in the frame 105. In the example shown in FIG. 1B, the server opening 112 may be located at or proximate to the top portion 106 of the frame 105.

The server basket 100 may include a handle assembly 120, as shown in FIG. 1A. The handle assembly 120 may allow the server basket 100 to be lifted from the immersion tank 250. The handle assembly 120 may include a handle 121. The handle assembly 120 may include an upright member 122 extending upward from the frame 105. The upright member 122 may be substantially parallel to a cable management housing 115. The handle assembly 120 may include 121 a handle support member 123 extending from the upright member 122 to the cable management housing 115. The handle 121 may be mounted to the handle support member 123. The handle 121 may be mounted to the top surface of the handle support member 123. In another example, the handle assembly 120 may include a lifting eye to allow the server basket 100 to be hoisted by, for example, a server crane.

To provide access to the server opening 112, the handle assembly 120 may be removable from the frame 105 or attached to the frame by a hinge that allows the handle assembly to pivot away from the server opening. Similarly, the cable management housing 115 may be attached to the frame 105 by a hinge 131 that allows the cable management housing to pivot away from the server opening 112, as shown in FIGS. 12C-E.

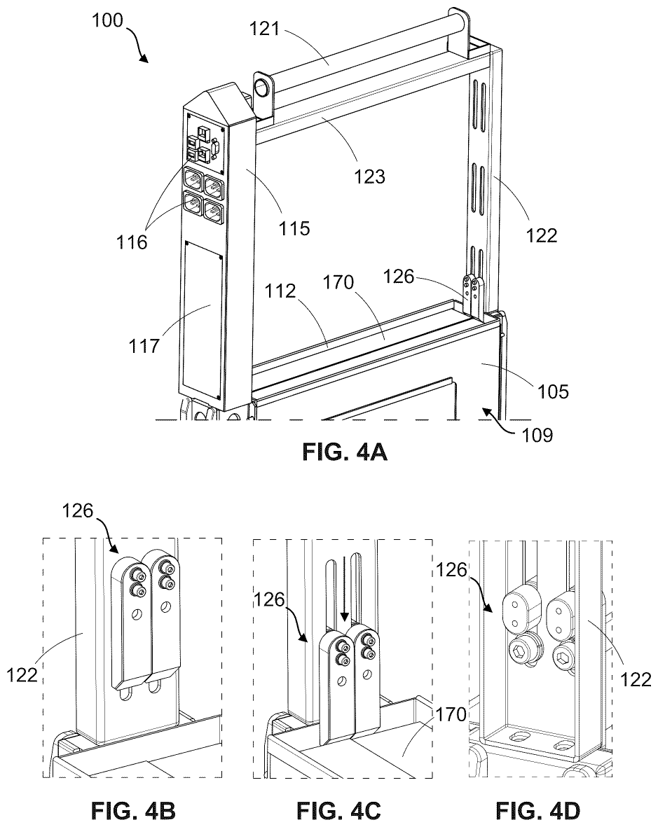

The server basket 100 may include a server retention device 126 that is configured to retain the server 170 in the server cavity 101. In the example shown in FIG. 4A, the server retention device 126 may include a wedge that is attached to the upright member 122. The upright member 122 may include slotted holes that allow for vertical repositioning of the wedge. Alternately, the wedge may include slotted holes that allow for vertical repositioning of the wedge. After the server 170 is installed into the server cavity 101, the wedge 126 may be repositioned (i.e., wedged) downward into the server cavity 101 between the frame 105 and the server 170 until contact is made with both. The wedge may then be fastened to the upright member 122, effectively securing the server 170 in place. FIGS. 4B-D show steps for installing the server retention device 126 after the server is installed in the server cavity. FIG. 4B shows the server retention device 126 loosely and slidably attached to the upright member 122 of the handle assembly 120. FIG. 4C shows the server retention device 126 being repositioned downward to contact the server 170. FIG. 4D shows fasteners of the server retention device 126 being tightened to secure the device relative to the server 170.

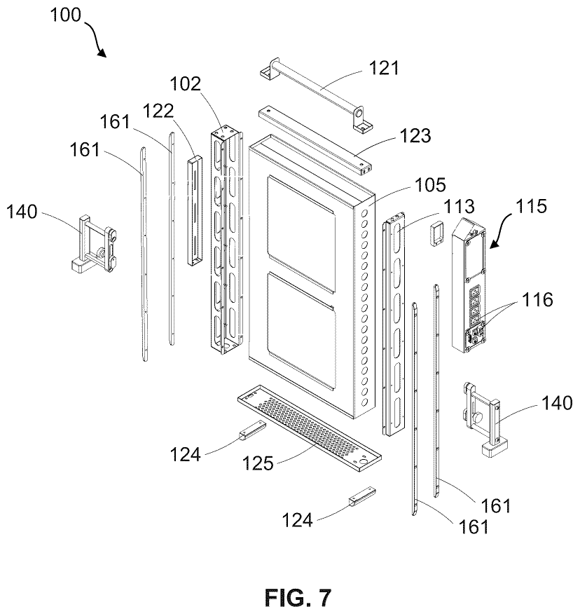

The server basket 100 may include a bottom plate 125 as shown in FIG. 7. The bottom plate 125 may be a perforated plate that allows fluid to drain from the server basket 100 when the server basket is lifted from the immersion tank 250.

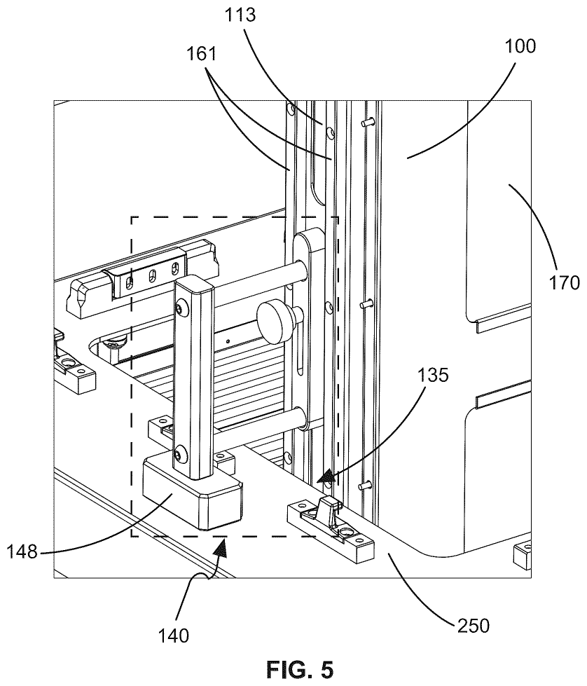

The server basket 100 may include a guide system 160 that allows the server basket to be accurately positioned within the immersion tank 250. The guide system 160 may include one or more guide rails 161 on the left side portion 110 and one or more guide rails 161 on the right side portion 111. As shown in the example of FIGS. 5-7, the server basket 100 may include a pair of guide rails 161 on each of the left and right side portions of the frame 105. During insertion into the immersion tank 250, the guide rails 161 may engage corresponding channels in the immersion tank 250 that guide the server basket 100 toward a dedicated location in the immersion tank. In one example, the guide system 160 may result in the server 170 being properly positioned to electrically connect to a bus bar in the immersion tank 250. When multiple server baskets 100 are installed in the immersion tank 250, respective guide systems 160 may prevent adjacent servers from contacting each other.

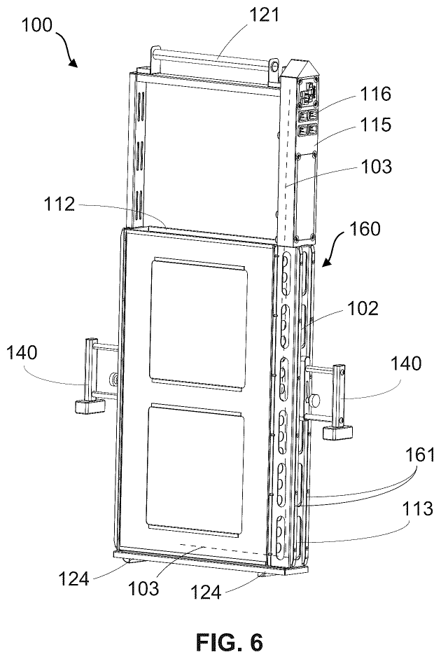

The server basket 100 may have one or more feet 124. The feet may be attached to the bottom portion 107 of the frame 105, as shown in FIGS. 6 and 7. The feet 124 may be made of a material that is compatible with the dielectric fluid 300.

The server basket 100 may include a cable routing compartment 102. The cable routing compartment 102 may be located adjacent to the server cavity 101, as shown in FIGS. 1 and 12F. The cable routing compartment 102 may provide a cable pathway 103 that extends from the server cavity 101 to the cable management housing 115. The cable routing compartment 102 may protect power and data cables from being damaged when the server is being inserted into or removed from the server cavity 101.

The server basket 100 may include the cable management housing 115. The cable management housing 115 may include one or more ports 116, as shown in FIG. 4A, to facilitate data and power transfer. The ports 116 may be physical ports that include, for example, one or more power supply ports, USB ports, PCI slots, video ports, serial ports, and/or ethernet ports. The cable management housing 115 may extend upward from the top portion of the frame 105. The cable management housing 115 may be attached to the cable routing compartment 102. When the server basket 100 is installed in the immersion tank 250, the cable management housing 115 may be located above a liquid level 305 of the dielectric fluid 300. Consequently, the ports 116 may be accessible without reaching into the dielectric fluid 300.

The cable management housing 115 may include one or more devices for strengthening a signal. For example, the cable management housing 115 may include a signal repeater 117. The signal repeater 117 may be a signal amplifier that enhances signal strength and quality of, for example, a wireless signal that is received from a cellular tower, Wi-Fi router, or radio transmitter. The signal repeater 117 may include an antenna to receive a weak signal. The signal repeater 117 may include circuitry to boost a power level of the weak signal and transmit the signal through the antenna. Locating the signal repeater 117 in the cable management housing 115 may result in the signal repeater being located above the liquid level 305 when the server is immersed in dielectric fluid 300, which may allow the antenna to more effectively receive and transmit signals than if it were immersed in the dielectric fluid.

To hold the server basket 100 in a raised position (e.g., during removal or servicing), as shown in FIG. 9, the server basket 100 may include support arms 140. The support arms 140 may extend outward from the frame 105 in opposing directions. The support arms 140 may be configured to rest on a top surface of the immersion tank 250 and support the server basket 100 in a fixed position with respect to the tank opening 251. The server basket 100 may have a first support arm 140 extending from the left side portion 110 and a second support arm 140 extending from the right side portion 111.

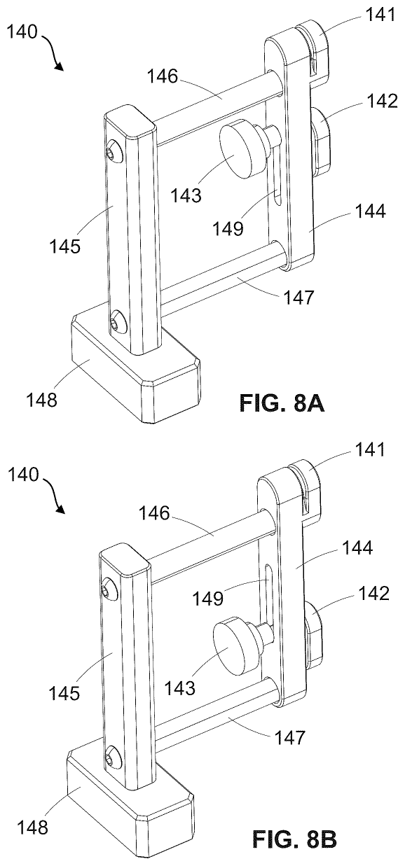

The support arms 140 may be removable support arms 140, as shown in FIGS. 5-8B. When the server basket 100 is lifted from the immersion tank 250, the removable support arms may be subsequently attached to the server basket. The removable support arms may support the server basket in a drying position, as shown in FIG. 5. Each removable support arm 140 may include a fixed clip 141 and a movable clip 142. FIG. 8A shows the movable clip 142 in an unsecured position. FIG. 8B shows the movable clip 142 in a secured position. During installation, the fixed clip 141 may be inserted into a first side opening 113 in the frame 105, and the movable clip 142 may be adjusted and inserted into a second side opening 113 in the frame 105. The movable clip 142 may then be secured by, for example, an adjustment screw 143. The adjustment screw 143 may include a knob that allows the adjustment screw to be tightened by hand.

The server basket 100 may include a clip receiver 114 on each of the left side portion 110 and the right side portion 111. Each clip receiver 114 may include a plurality of openings 113 arranged in a column and extending from the bottom portion 107 to the top portion 106. The plurality of openings 113 may provide multiple positions to attach the removable support arms 140, which allow the height of the server basket 100 to be adjusted relative to the top surface of the immersion tank 250 to allow the server basket to be supported at a suitable height above the liquid level 305.

In the example shown in FIG. 8A and 8B, the removable support arm 140 may include a first member 144 and a second member 145 that are substantially parallel and offset by a distance. The distance may be dictated by, for example, dimensions of the immersion tank 250, the server basket 100, and a clearance gap 135 between the server basket 100 and the tank opening 251, as shown in FIG. 5. The fixed clip 141 may be attached to or integrally formed in the first member 144. The movable clip 142 may be movable about a slot in the first member 144. The removable support arm 140 may include a first offset member 146 that extends from the first member 144 to the second member 145. The removable support arm 140 may include a second offset member 147 that extends from the first member 144 to the second member 145.

As shown in FIG. 5, the removable support arm 140 may include a pad 148. The pad 148 may be configured to protect the top surface of the immersion tank 250 from being scratched by the removable support arm 140. The pad 148 may be attached to a bottom of the second member 145. Avoiding scratching the top surface of the immersion tank may be desirable, since the surface may serve as a sealing surface for the lid 252.

In another example, the support arms 140 may be hinged support arms, as shown in FIGS. 9-11C. The hinged support arm may provide a low-cost, integral solution for supporting the server basket 100 in the drying position, as shown in FIG. 9. The hinged support arm may have an arm 181 with a slot 184 formed therein. The hinged support arm may include a mounting bracket 185 attached to the frame 105. The hinged support arm may include a pin 183 attached to the mounting bracket 185. The pin may extend through the slot 184 in the arm 181. The arm 181 may be movable about the pin 183 to facilitate transitioning between stowed and deployed states.

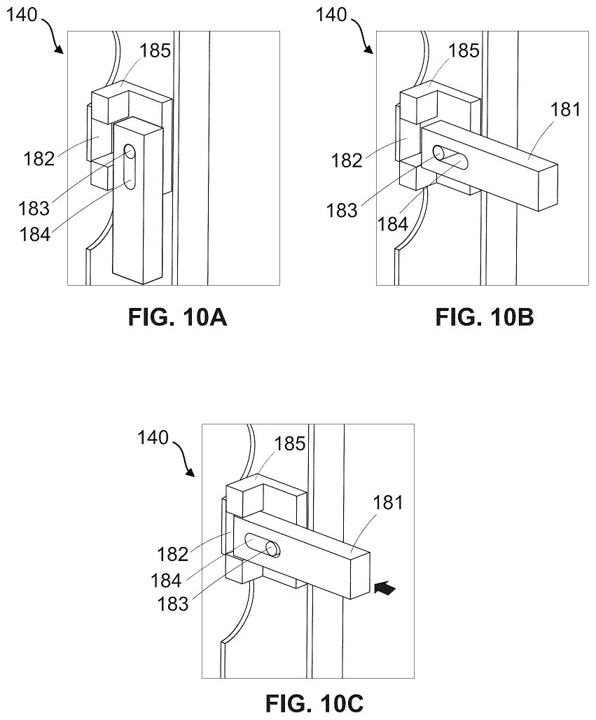

FIG. 9 shows the server basket 100 with two hinged support arms. The hinged support arms may be configured to transition from a stowed position to a deployed position. FIGS. 10A-C show cross-sectional side views of steps of deploying the hinged support arm. FIG. 10A shows the hinged support arm 140 in a stowed position. FIG. 10B shows the hinged support arm 140 rotated upward. FIG. 10C shows the hinged support arm 140 inserted into a retention pocket 182 to hold the hinged support arm in a deployed position.

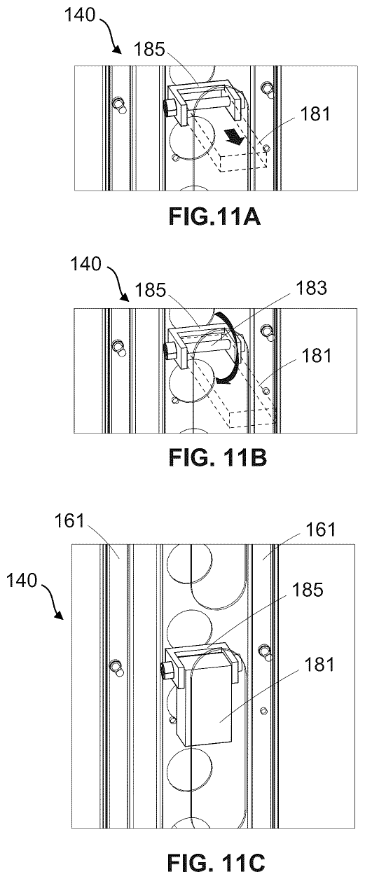

FIGS. 11A-C show steps for stowing the hinged support arm of FIG. 9. FIG. 11A shows an arm 181 being withdrawn from the retention pocket 182. FIG. 11B shows the support arm being rotated downward about the pin. FIG. 11C shows the support arm in the stowed position.

In another example, the support arms 140 may be spring-loaded support arms, as shown in FIG. 3C. The spring-loaded support arms may automatically deploy when the server basket 100 is raised from the immersion tank 250 and the support arms moves above the tank opening 251. Consequently, one person can lift the server basket 100 and not require assistance from a second person to deploy the support arms 140. The spring-loaded support arms are suitable for robotic extraction of the server basket 100 when no human is present to manually deploy the support arms.

FIGS. 12A-F show an alternative embodiment of the server basket 100 of FIG. 1A. The cable management housing 115 may be attached to the frame 105 by a hinge 131, as shown in FIG. 12D. The server basket 100 may include a top cover 130 that is attached to the cable management housing 115. Rotation of the cable management housing 115 may cause the top cover 130 to rotate about the hinge 131 and reveal the server opening 112, thereby enabling insertion and removal of the server 170 from the server cavity 101. The top cover 130 may include a lifting eye 132 that allows the server basket 100 to be lifted by a crane or hoist. FIG. 12 F shows a cross-sectional rear view of the server basket 100, exposing a cable pathway 103 extending from the server cavity 101, through the cable routing compartment 102, and to the cable management housing 115.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A server basket for use in an immersion tank, the server basket comprising:
a frame having a bottom portion, a top portion, a front portion, a rear portion, a first side portion, and a second side portion opposite the first side portion;
a server cavity in the frame and configured to receive a computer server;
a cable management housing extending from the top portion, the cable management housing comprising one or more power and data connections; and
a cable pathway extending from the server cavity to the cable management housing.

2. The server basket of claim 1, further comprising a signal repeater in the cable management housing.

3. The server basket of claim 1, further comprising a handle assembly having a first end attached to the cable management housing and a second end attached to the frame.

4. The server basket of claim 1, further comprising:
a first support arm attached to the first side portion; and
a second support arm attached to the second side portion,
wherein the first support arm and the second support arm, together, are configured to support the server basket in an upright orientation when resting on a support surface.

5. The server basket of claim 4, wherein the first support arm comprises a pin attached to the frame and a support arm having a slot through which the pin extends, the support arm configured to transition from a stowed configuration to a deployed configuration.

6. The server basket of claim 4, wherein the first support arm comprises a spring-loaded arm that is configured to transition from a stowed configuration to a deployed configuration.

7. The server basket of claim 4, further comprising:
a first clip receiver attached to the first side portion, the first clip receiver comprising a first plurality of openings and configured to receive a first removable support arm; and
a second clip receiver attached to the second side portion, the second clip receiver comprising a second plurality of openings configured to receive a second removable support arm,
wherein the first support arm and the second support arm, together, are configured to support the server basket in an upright orientation when resting on a support surface.

8. A server basket comprising:
a frame having a server cavity configured to receive a computer server;
a cable management housing at or proximate to a top portion of the frame, the cable management housing comprising a plurality of power and data connections; and
a signal repeater within the cable management housing.

9. The server basket of claim 8, further comprising a guide system comprising:
a first guide rail on a first side of the frame; and
a second guide rail on a second side of the frame.

10. The server basket of claim 8, further comprising a cable pathway extending from the server cavity to the cable management housing, wherein the cable pathway passes through a cable routing compartment.

11. The server basket of claim 10, further comprising:
a hinge attaching the cable management housing to the frame;
a top cover attached to the cable management housing; and
a lifting eye attached to the top cover,
wherein rotating the cable management housing about the hinge reveals a server opening in the frame that provides access to the server cavity.

12. The server basket of claim 8, further comprising:
a first support arm attached to a first side portion of the frame; and
a second support arm attached to a second side portion of the frame.

13. The server basket of claim 12, wherein the first support arm comprises a pin attached to the frame and a support arm having a slot through which the pin extends, the support arm configured to transition from a stowed configuration to a deployed configuration.

14. The server basket of claim 12, wherein the first support arm comprises a spring-loaded arm that is configured to transition from a stowed configuration to a deployed configuration.

15. The server basket of claim 12, wherein the first support arm is removable and comprises a pad configured to contact a top surface of an immersion tank.

16. A server basket for use in an immersion tank, the server basket comprising:
a frame having a bottom portion, a top portion, a front portion, a rear portion, a first side portion, and a second side portion;
a server cavity in the frame and configured to receive a computer server;
a cable management housing extending upward from the frame, the cable management housing comprising one or more power and data ports;
a handle assembly extending from the cable management housing to the frame; and
a server retention device slidably attached to the handle assembly and configured to retain the computer server in the server cavity.

17. The server basket of claim 16, further comprising:
a first support arm attached to the first side portion; and
a second support arm attached to the second side portion.

18. The server basket of claim 17, wherein the first support arm comprises a pin attached to the frame and a support arm having a slot through which the pin extends, the support arm configured to transition from a stowed configuration to a deployed configuration.

19. The server basket of claim 17, wherein the first support arm comprises a spring-loaded arm that is configured to transition from a stowed configuration to a deployed configuration.

20. The server basket of claim 17, wherein the first support arm is removable and comprises a fixed clip, a movable clip, and an adjustment screw to secure the movable clip in a position relative to the fixed clip.
